(19) United States
(12) Patent Application Publication
(10) Pub. No.: US 2025/0294754 A1
(43) Pub. Date: Sep. 18, 2025

(54) INTEGRATED CIRCUIT MEMORY DEVICES AND ELECTRONIC SYSTEMS INCLUDING THE SAME

(71) Applicant: Samsung Electronics Co., Ltd., Suwon-si (KR)

(72) Inventors: Yuyeon Kim, Suwon-si (KR); Siyeong Yang, Suwon-si (KR); Chaeho Kim, Suwon-si (KR); Jaemin Jung, Suwon-si (KR)

(21) Appl. No.: 19/012,055

(22) Filed: Jan. 7, 2025

(30) Foreign Application Priority Data
Mar. 12, 2024 (KR) 10-2024-0034720

(51) Int. Cl. H10B 43/27; H01L 23/00; H01L 25/065; H01L 25/18; H10B 43/10; H10B 43/35; H10B 80/00

(52) U.S. Cl. CPC H10B 43/27; H01L 24/08; H01L 25/0657; H01L 25/18; H10B 43/10; H10B 43/35; H10B 80/00; H01L 2224/08145; H01L 2924/1431; H01L 2924/14511

(57) ABSTRACT

An integrated circuit device includes a substrate having a peripheral circuit structure thereon, and a cell array structure extending on the peripheral circuit structure. The cell array structure includes: a gate stack including a plurality of insulation layers and a plurality of gate lines alternately arranged on the substrate, a plurality of channel structures each penetrating through the gate stack in a vertical direction perpendicular to a top surface of the substrate and comprising a monocrystalline channel layer, and a common source line, which extends on the gate stack, is in contact with the channel layer of the channel structure, and includes a semiconductor layer and a cover layer provided between the semiconductor layer and the channel layer.

### REFERENCE TO PRIORITY APPLICATION

This application claims priority under 35 U.S.C. § 119 to Korean Patent Application No. 10-2024-0034720, filed Mar. 12, 2024, the disclosure of which is hereby incorporated herein by reference.

### BACKGROUND

The inventive concept relates to integrated circuit memory devices and electronic systems including the same and, more particularly, to integrated circuit memory devices having utilize vertically-integrated non-volatile memory elements and electronic systems including the same.

In an electronic system requiring high capacity data storage, an integrated circuit memory device with high integration is need, and thus, methods of increasing the data storage capacity of integrated circuit memory devices are being researched. For example, according to one method of increasing the data storage capacity of an integrated circuit memory device, memory strings having 3-dimensionally arranged memory cells instead of 2-dimensionally arranged memory cells have been proposed.

### SUMMARY

The inventive concept provides an integrated circuit memory device with improved operational reliability and an electronic system including the same.

According to an aspect of the inventive concept, there is provided an integrated circuit memory device including a peripheral circuit structure provided on a substrate, and a “memory” cell array structure extending on the peripheral circuit structure. The cell array structure includes: a common source line including a first semiconductor layer, a second semiconductor layer, and a third semiconductor layer sequentially stacked on the substrate, a gate stack including a plurality of insulation layers and a plurality of gate lines alternately arranged on the common source line, and a plurality of channel structures each penetrating through the gate stack in a vertical direction perpendicular to a top surface of the substrate and including a monocrystalline channel layer. According to some embodiments, the second semiconductor layer extends from both side walls of a channel structure into the channel structure and is in contact with the channel layer. The second semiconductor layer includes a second semiconductor material layer and a cover layer provided between the channel layer and the second semiconductor material layer.

According to another aspect of the inventive concept, there is provided an integrated circuit memory device including a peripheral circuit structure provided on a substrate, and a “memory” cell array structure extending on the peripheral circuit structure. The memory cell array structure includes a gate stack including a plurality of insulation layers and a plurality of gate lines alternately arranged on the substrate, a plurality of channel structures each penetrating through the gate stack in a vertical direction perpendicular to a top surface of the substrate and including a monocrystalline channel layer, and a common source line extending on the gate stack. The common source line is in contact with the channel layer of the channel structure, and the common source line includes a semiconductor layer and a cover layer provided between the semiconductor layer and the channel layer.

According to another aspect of the inventive concept, there is provided an electronic system including a main substrate, an integrated circuit memory device on the main substrate, and a controller electrically connected to the integrated circuit memory device on the main substrate. The integrated circuit memory device includes a peripheral circuit structure provided on a substrate, and a “memory” cell array structure extending on the peripheral circuit structure. The cell array structure includes a common source line including a first semiconductor layer, a second semiconductor layer, and a third semiconductor layer sequentially stacked on the substrate. A gate stack is provided, which includes a plurality of insulation layers and a plurality of gate lines alternately arranged on the common source line. A plurality of channel structures are provided that individually penetrate through the gate stack in a vertical direction perpendicular to a top surface of the substrate and include a monocrystalline channel layer. According to some embodiments, the second semiconductor layer extends from both side walls of a channel structure into the channel structure and is in contact with the channel layer. The second semiconductor layer may include a second semiconductor material layer and a cover layer provided between the channel layer and the second semiconductor material layer.

### BRIEF DESCRIPTION OF THE DRAWINGS

Embodiments of the inventive concept will be more clearly understood from the following detailed description taken in conjunction with the accompanying drawings in which:

FIG. 1 is a block diagram showing an integrated circuit memory device according to embodiments;

FIG. 2 is an equivalent circuit diagram of a memory cell array of an integrated circuit memory device according to embodiments;

FIG. 3 is a schematic perspective view of an integrated circuit memory device according to embodiments;

FIG. 4 is a plan layout diagram showing some components of a cell array structure of an integrated circuit memory device according to embodiments;

FIG. 5 is a cross-sectional view of some regions of a peripheral circuit structure and a cell array structure of an integrated circuit memory device according to embodiments;

FIG. 6 is an enlarged cross-sectional view of a portion EX1 of FIG. 5;

FIG. 7 is a cross-sectional view of some regions of a peripheral circuit structure and a cell array structure of an integrated circuit memory device according to embodiments;

FIG. 8 is an enlarged cross-sectional view of a portion EX2 of FIG. 7;

FIG. 9 is a diagram schematically showing an electronic system including an integrated circuit memory device, according to an embodiment;

FIG. 10 is a schematic perspective view of an electronic system including an integrated circuit memory device, according to embodiments;

FIG. 11 is a schematic cross-sectional view of semiconductor packages according to embodiments;

FIGS. 12A, 12B, and 12C are cross-sectional views for describing a method of manufacturing an integrated circuit memory device, according to embodiments; and

FIGS. 13A, 13B, and 13C are cross-sectional views for describing a method of manufacturing an integrated circuit memory device, according to embodiments.

### DETAILED DESCRIPTION OF THE EMBODIMENTS

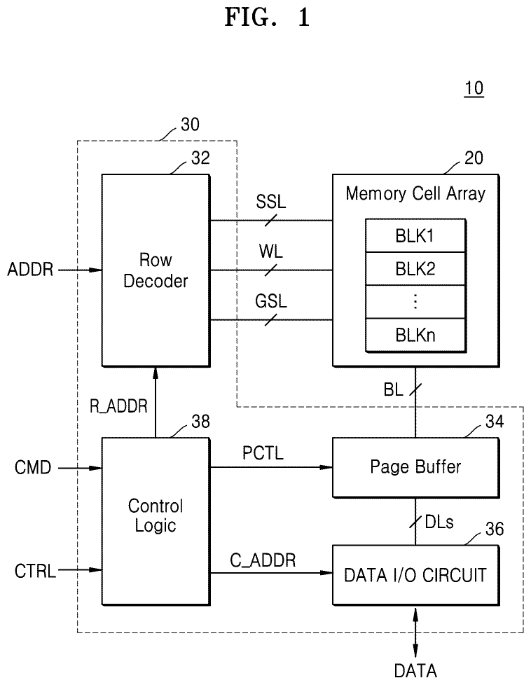

FIG. 1 is a block diagram showing an integrated circuit memory device 10 according to embodiments. Referring to FIG. 1, the integrated circuit memory device 10 may include a memory cell array 20 and a peripheral circuit 30. The memory cell array 20 may include a plurality of memory cell blocks BLK1, BLK2, . . . , and BLKn, and each of the memory cell blocks BLK1, BLK2, . . . , and BLKn may include a plurality of memory cells. The memory cell blocks BLK1, BLK2, . . . , and BLKn may be connected to the peripheral circuit 30 through bit lines BL, word lines WL, a string select line(s) SSL, and a ground select line(s) GSL. As shown, the peripheral circuit 30 may include a row decoder 32, a page buffer 34, a data input/output circuit 36, and a control logic 38. Although not shown in FIG. 1, the peripheral circuit 30 may further include an input/output interface, column logic, a voltage generator, a pre-decoder, a temperature sensor, a command decoder, an address decoder, an amplifier circuit, etc.

The memory cell array 20 may be connected to the page buffer 34 through the bit lines BL, and the row decoder 32 may be connected to the row decoder 32 through the word lines WL, the string select line(s) SSL, and the ground select line(s) GSL. In the memory cell array 20, the memory cells included in each of the memory cell blocks BLK1, BLK2, . . . , and BLKn may each be a flash memory cell. The memory cell array 20 may include a 3-dimensional memory cell array. The 3D memory cell array may include a plurality of NAND strings, and the NAND strings may each include a plurality of memory cells respectively connected to a plurality of word lines WL vertically stacked on a substrate.

The peripheral circuit 30 may receive an address ADDR, a command CMD, and a control signal CTRL from a device external to the integrated circuit memory device 10 and may transmit and receive data to and from the device outside the integrated circuit memory device 10. The row decoder 32 may select at least one of the memory cell blocks BLK1, BLK2, . . . , and BLKn in response to an address ADDR from the outside and select the word line WL, the string select line SSL, and the ground select line GSL corresponding to a selected memory cell block. The row decoder 32 may transmit a voltage for performing a memory operation to the word line WL corresponding to the selected memory cell block.

The page buffer 34 may be connected to the memory cell array 20 through the bit lines BL. The page buffer 34 may operate as a write driver during a program operation and apply a voltage according to the data DATA to be stored in the memory cell array 20 to the bit line BL, and may also operate as a sense amplifier during a read operation and sense the data DATA stored in the memory cell array 20. The page buffer 34 may operate according to a control signal PCTL provided from the control logic 38.

The data input/output circuit 36 may be connected to the page buffer 34 through data lines DLs. During a program operation, the data input/output circuit 36 may receive the data DATA from a memory controller (not shown) and provide the data DATA to be programmed to the page buffer 34 based on a column address C_ADDR provided from the control logic 38. The data input/output circuit 36 may provide the data DATA to be read. which is stored in the page buffer 34, to the memory controller based on the column address C_ADDR provided from the control logic 38 during a read operation. The data input/output circuit 36 may also transmit an address or a command input thereto to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data input/output circuit 36. The control logic 38 may generate various internal control signals used in the integrated circuit memory device 10 in response to the control signal CTRL. For example, the control logic 38 may adjust the level of a voltage provided to the word line WL and the bit line BL when a memory operation like a program operation or an erase operation is performed.

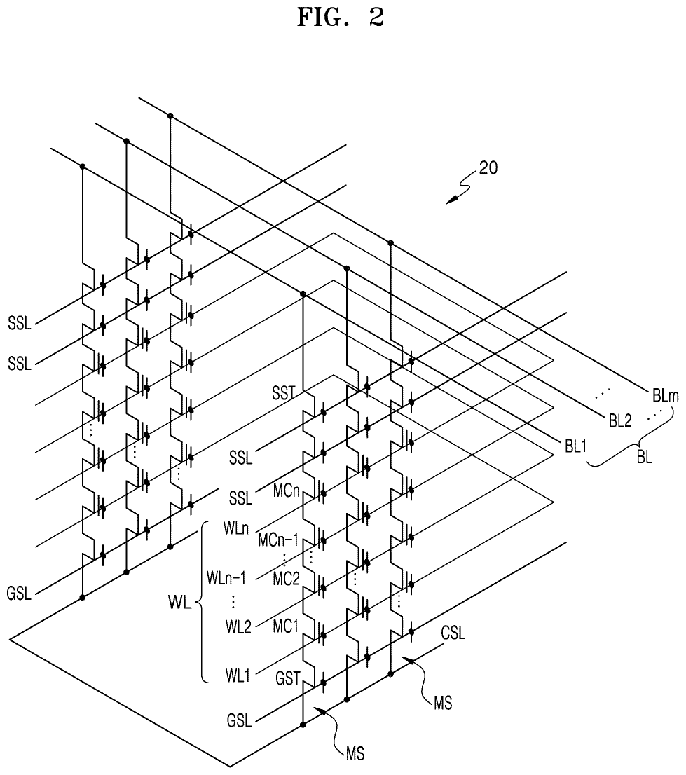

FIG. 2 is an equivalent circuit diagram of the memory cell array 20 of an integrated circuit memory device according to embodiments. Referring to FIG. 2, the memory cell array 20 may include a plurality of memory cell strings MS. The memory cell array 20 may include a plurality of bit lines BL: BL1, BL2, . . . , and BLm, a plurality of word lines WL: WL1, WL2, . . . , WLn-1, and WLn, at least one string select line SSL, at least one ground select line GSL, and a common source line CSL. The memory cell strings MS may be formed between the bit lines BL: BL1, BL2, . . . , and BLm and the common source line CSL. Although FIG. 2 shows a case in which the memory cell strings MS each include two string select lines SSL, the inventive concept is not limited thereto. For example, the memory cell strings MS may each include one string select line SSL.

The memory cell strings MS may each include the string select transistor SST, the ground select transistor GST, and a plurality of memory cell transistors MC1, MC2, . . . , MCn-1, and MCn. A drain region of the string select transistor SST may be connected to the bit lines BL: BL1, BL2, . . . , and BLm, and a source region of the ground select transistor GST may be connected to the common source line CSL. The common source line CSL may be a region in which source regions of a plurality of ground select transistors GST are connected in common. The string select transistor SST may be connected to the string select line SSL, and the ground select transistor GST may be connected to the ground select line GSL. The memory cell transistors MC1, MC2, . . . , MCn-1, and MCn may be connected to the word lines WL: WL1, WL2, . . . , WLn-1, and WLn, respectively.

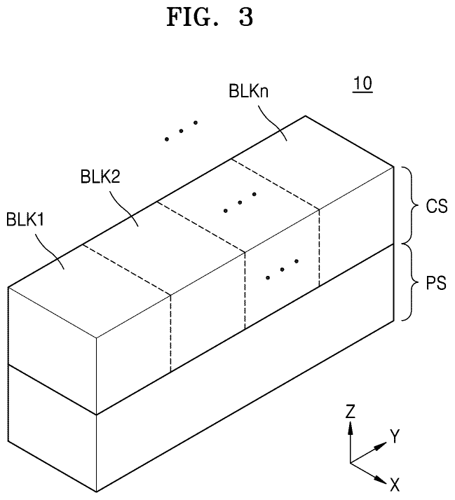

FIG. 3 is a schematic perspective view of the integrated circuit memory device 10 according to embodiments. Referring to FIG. 3, the integrated circuit memory device 10 may include a cell array structure CS and a peripheral circuit structure PS that overlap each other in the vertical direction (Z direction). The cell array structure CS may include the memory cell array 20 described with reference to FIGS. 1 and 2, and the peripheral circuit structure PS may include the peripheral circuit 30 described with reference to FIG. 1. As shown, the cell array structure CS may include the memory cell blocks BLK1, BLK2, . . . , and BLKn. The memory cell blocks BLK1, BLK2, . . . , and BLKn may each include 3-dimensionally arranged memory cells.

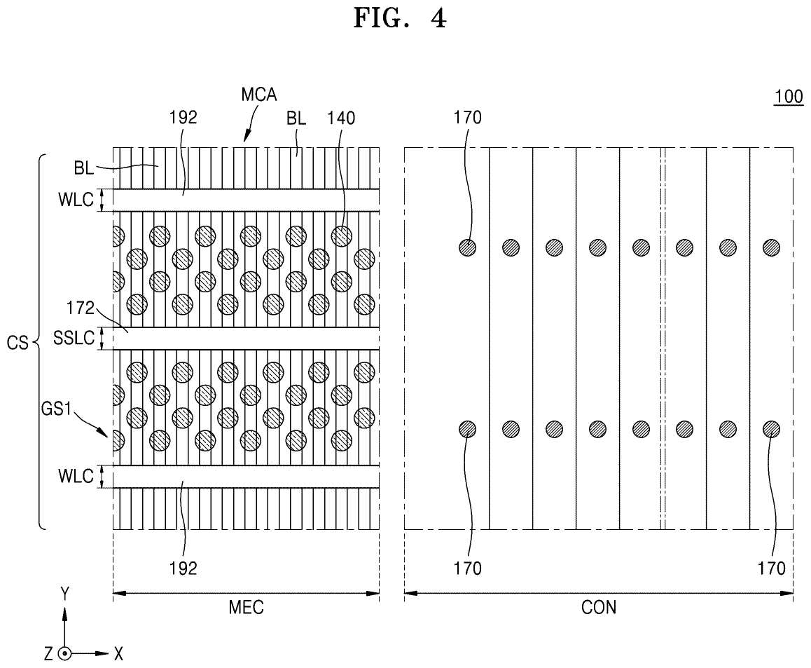

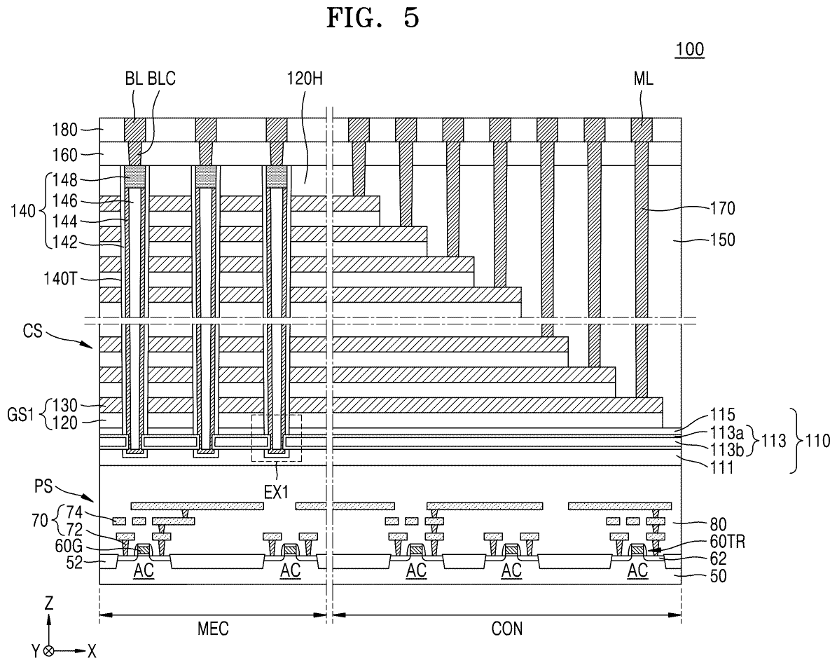

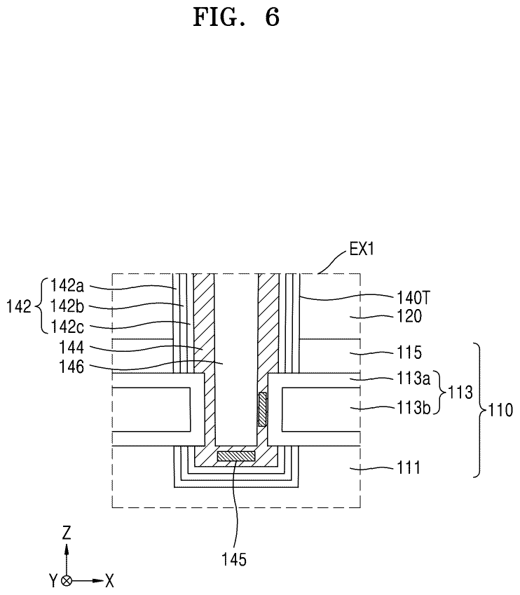

FIG. 4 is a plan layout diagram showing some components of the cell array structure CS of an integrated circuit memory device 100 according to embodiments. FIG. 5 is a cross-sectional view of some regions of the peripheral circuit structure PS and the cell array structure CS of the integrated circuit memory device 100 according to embodiments. FIG. 6 is an enlarged cross-sectional view of a portion EX1 of FIG. 5.

Referring to FIGS. 4, 5, and 6, the integrated circuit memory device 100 may include the peripheral circuit structure PS and the cell array structure CS, which extends on the peripheral circuit structure PS and overlaps the peripheral circuit structure PS in the vertical direction (Z direction). The peripheral circuit structure PS may include a substrate 50, peripheral circuit transistors 60TR arranged on the substrate 50, and a peripheral circuit wiring structure 70 for mutually connecting the peripheral circuit transistors 60TR or connecting the peripheral circuit transistors 60TR to components in the cell array structure CS.

The substrate 50 may include a semiconductor material, e.g., a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or an epitaxial layer. According to an embodiment, the substrate 50 may include a silicon-on-insulator (SOI) substrate or a germanium-on-insulator (GeOI) substrate.

An active region AC may be defined on the substrate 50 by a device isolation layer 52. The device isolation layer 52 may be provided in a device isolation trench (not shown) formed in the substrate 50. According to embodiments, the device isolation layer 52 may include silicon oxide, silicon nitride, silicon oxynitride, or a combination thereof.

The peripheral circuit transistors 60TR may be formed on a plurality of active regions AC. A peripheral circuit transistor 60TR may include a peripheral circuit gate 60G and source/drain regions 62 arranged on portions of the substrate 50 on both sides of the peripheral circuit gate 60G. The peripheral circuit transistors 60TR may constitute a plurality of peripheral circuits included in the peripheral circuit structure PS. The plurality of peripheral circuits consisting of the peripheral circuit transistors 60TR may include various circuits included in the peripheral circuit 30 described with reference to FIG. 1. For example, the plurality of peripheral circuits may each include the row decoder 32, the page buffer 34, the data input/output circuit 36, the control logic 38, and the common source line driver 39 shown in FIG. 1.

The peripheral circuit wiring structure 70 may include a plurality of peripheral circuit contacts 72 and a plurality of peripheral circuit wiring layers 74. The plurality of peripheral circuit wiring layers 74 may have a multi-layered structure including a plurality of metal layers arranged at different vertical levels. At least some of the plurality of peripheral circuit wiring layers 74 may be configured to be electrically connected to the peripheral circuit transistors 60TR. The plurality of peripheral circuit contacts 72 may be configured to interconnect the peripheral circuit transistors 60TR and selected some of the plurality of peripheral circuit wiring layers 74. The peripheral circuit wiring structure 70 may include tungsten, titanium, tantalum, copper, aluminum, titanium nitride, tantalum nitride, tungsten nitride, or a combination thereof.

An interlayer insulation layer 80 is provided on the substrate 50 and may cover the peripheral circuit transistors 60TR and the peripheral circuit wiring structure 70. The interlayer insulation layer 80 may include, for example, a silicon oxide layer, a silicon nitride layer, a SiON layer, a SiOCN layer, or a combination thereof.

The cell array structure CS may be provided on the interlayer insulation layer 80. The cell array structure CS may include a memory cell region MEC where a memory cell array MCA is provided, and connection regions CON arranged on both sides of the memory cell region MEC in a first horizontal direction (X direction). The memory cell array MCA shown in FIG. 4 may correspond to the memory cell array 20 described with reference to FIGS. 1 and 2.

The cell array structure CS may include a common source line 110 extending on the peripheral circuit structure PS, a gate stack GS1 extending on the common source line 110, and a plurality of channel structures 140. The common source line 110 may serve as a source region that supplies current to memory cell arrays MCAs formed in the cell array structure CS. The common source line 110 may correspond to the common source line CSL described with reference to FIG. 2. Although FIG. 5 shows that the common source line 110 is integrally formed across the memory cell area MEC and the connection regions CON, the inventive concept is not limited thereto. For example, a portion of the common source line 110 provided in the memory cell region MEC and a portion of the common source line 110 provided in a connection region CON may be separated from each other.

The common source line 110 may include a first semiconductor layer 111, a second semiconductor layer 113, and a third semiconductor layer 115 sequentially stacked on the interlayer insulation layer 80 of the peripheral circuit structure PS. The first semiconductor layer 111 and the third semiconductor layer 115 may contact both sidewalls of a gate insulation layer 142 of a channel structure 140, respectively. The second semiconductor layer 113 may horizontally penetrate through the gate insulation layer 142 of the channel structure 140 on both sidewalls of the channel structure 140 and contact a channel layer 144 of the channel structure 140. The second semiconductor layer 113 may be directly connected to the channel layer 144 of the channel structure 140. The second semiconductor layer 113 may include a second semiconductor material layer 113b and a cover layer 113a surrounding the second semiconductor material layer 113b. The channel layer 144, the first semiconductor layer 111, and the third semiconductor layer 115 of the channel structure 140 may be spaced apart from the second semiconductor material layer 113b with the cover layer 113a therebetween.

According to embodiments, the first semiconductor layer 111, the second semiconductor material layer 113b, and the third semiconductor layer 115 may each include at least one of silicon (Si), germanium (Ge), silicon germanium (SiGe), gallium arsenide (GaAs), indium gallium arsenide (InGaAs), aluminum gallium arsenide (AlGaAs), and mixtures thereof. According to embodiments, the first semiconductor layer 111, the second semiconductor material layer 113b, and the third semiconductor layer 115 may each include a semiconductor doped with an impurity. For example, the first semiconductor layer 111, the second semiconductor material layer 113b, and the third semiconductor layer 115 may each include polysilicon doped with an n-type impurity. The n-type impurity may include, for example, phosphorus (P) or arsenic (As). Alternatively, the first semiconductor layer 111, the second semiconductor material layer 113b, and the third semiconductor layer 115 may each include polysilicon doped with a p-type impurity. The p-type impurity may include, for example, boron (B). According to embodiments, the first semiconductor layer 111, the second semiconductor material layer 113b, and the third semiconductor layer 115 may each have a crystal structure including at least one selected from among monocrystalline, amorphous, and polycrystalline.

According to embodiments, the cover layer 113a may include carbide, nitride, oxide, or a combination thereof. The carbide may include, for example, silicon carbonitride or silicon carbide. The nitride may include, for example, silicon nitride. The oxide may include, for example, silicon oxide. According to embodiments, the second semiconductor material layer 113b may not include a metal silicide 145 included in the channel layer 144 of the channel structure 140. This may be because the cover layer 113a prevents the metal silicide 145 from diffusing from the channel layer 144 to the second semiconductor material layer 113b.

According to embodiments, the second semiconductor material layer 113b may include a metal included in the metal silicide 145. For example, the second semiconductor material layer 113b may include about 0.04 at % or less of metal. When the metal silicide 145 is nickel silicide (Ni₂Si), the metal may be nickel (Ni).

The gate stack GS1 may be provided on the common source line 110. The gate stack GS1 may include a plurality of insulation layers 120 and a plurality of gate lines 130 alternately stacked in the vertical direction (Z direction). The plurality of insulation layers 120 may be provided between the common source line 110 and the lowermost gate line 130 and between the plurality of gate lines 130. Also, an uppermost insulation layer 120H from among the plurality of insulation layers 120 may cover the uppermost gate line 130. A portion of the gate stack GS1 extending on the memory cell region MEC may constitute the memory cell array MCA.

The plurality of insulation layers 120 may each include, for example, silicon oxide. The plurality of gate lines 130 may each include a metal such as tungsten, nickel, cobalt, and tantalum, a metal silicide such as tungsten silicide, nickel silicide, cobalt silicide, and tantalum silicide, doped polysilicon, titanium nitride, tantalum nitride, tungsten nitride, or a combination thereof.

According to embodiments, the plurality of gate lines 130 may correspond to the ground select line GSL (refer to FIG. 2), the word lines WL: WL1, WL2, . . . , WLn-1, and WLn (see FIG. 2), and at least one string select line SSL (refer to FIG. 2) constituting the memory cell string MS (refer to FIG. 2). For example, the lowermost gate line 130 may function as the ground select line GSL, two uppermost gate lines 130 may function as the string select lines SSL, and the remaining gate lines 130 may function as the word lines WL. Therefore, the memory cell string MS (refer to FIG. 2) in which the ground select transistor GST (refer to FIG. 2), the string select transistor SST (refer to FIG. 2), and memory cell transistors MC1, MC2, . . . , MCn-1, and MCn (refer to FIG. 2) are connected in series therebetween may be provided. According to embodiments, at least one of the gate lines 130 may function as a dummy word line, but the inventive concept is not limited thereto.

In the cell array structure CS, a plurality of word line cuts WLC may extend parallel to one another in the first horizontal direction (X direction). The plurality of word line cuts WLC may limit the width of the gate stack GS1 in a second horizontal direction (Y direction). The plurality of word line cuts WLC may be filled with a word line cut structure 192. The word line cut structure 192 may include an insulation layer, a polysilicon layer, a metal layer, or a combination thereof. For example, the word line cut structure 192 may include a silicon oxide layer, a silicon nitride layer, a polysilicon layer, a tungsten layer, or a combination thereof.

In the memory cell array MCA, two string select lines SSL (refer to FIG. 2) adjacent to each other in the second horizontal direction (Y direction) may be spaced apart from each other with a string select line cuts SSLC therebetween. The string select line cuts SSLC may be filled with a string select line cut structure 172. The string select line cut structure 172 may include, for example, an oxide film, a nitride film, or a combination thereof. At least some of the string select line cuts SSLC may be filled with, for example, an air gap. The term “air” used herein may refer to the atmosphere or other gases that may be present during a manufacturing process.

In the memory cell region MEC, the plurality of channel structures 140 may extend in the vertical direction (Z direction) through the gate stack GS1. The plurality of channel structures 140 may be spaced apart from one another at certain intervals in the first horizontal direction (X direction) and the second horizontal direction (Y direction). The plurality of channel structures 140 may each extend into the common source line 110. For example, the plurality of channel structures 140 may each penetrate through the second semiconductor layer 113 and the third semiconductor layer 115 and extend into the first semiconductor layer 111. The plurality of channel structures 140 may each include the gate insulation layer 142, the channel layer 144, a buried insulation layer 146, and a conductive plug 148 arranged in a channel hole 140T.

The gate insulation layer 142 and the channel layer 144 may be sequentially arranged on the inner wall of the channel hole 140T. For example, the gate insulation layer 142 may be conformally formed on the inner wall of the channel hole 140T and the bottom surface of the channel hole 140T, and the channel layer 144 may be conformally formed on the gate insulation layer 142.

The gate insulation layer 142 may include a tunneling dielectric layer 142a, a charge storage layer 142b, and a blocking dielectric layer 142c sequentially arranged on sidewalls of the channel hole 140T. The relative thicknesses of the tunneling dielectric layer 142a, the charge storage layer 142b, and the blocking dielectric layer 142c constituting the gate insulation layer 142 are not limited to those illustrated in FIG. 6, and various modifications may be made therein.

The tunneling dielectric layer 142a may include silicon oxide, hafnium oxide, aluminum oxide, zirconium oxide, tantalum oxide, etc. The charge storage layer 142b is a region in which electrons that passed through the tunneling dielectric layer 142a from a channel layer 144 may be stored and may include silicon nitride, boron nitride, or silicon boron nitride. The blocking dielectric layer 142c may include silicon oxide or a metal oxide having a higher permittivity than silicon oxide. The metal oxide may include hafnium oxide, aluminum oxide, zirconium oxide, tantalum oxide, or a combination thereof.

The channel layer 144 may have a cylindrical shape. The channel layer 144 may include monocrystalline silicon. The monocrystalline silicon constituting the channel layer 144 may be monocrystalline silicon crystallized through metal induced lateral crystallization (MILC). The channel layer 144 may include the metal silicide 145. Crystallization of monocrystalline silicon constituting the channel layer 144 may be performed through MILC using the metal silicide 145 as a seed. The metal silicide 145 may include, for example, nickel silicide, cobalt silicide, platinum silicide, or a combination thereof. According to embodiments, monocrystalline silicon constituting the channel layer 144 may be doped with impurities. Impurities doped into the monocrystalline silicon may include, for example, oxygen (O), carbon (C), nitrogen (N), or a combination thereof. The impurities doped into the monocrystalline silicon may prevent amorphous silicon from being crystallized by heat during a process of manufacturing the integrated circuit memory device 100, which will be described later.

According to embodiments, the channel layer 144 may contact the second semiconductor layer 113 at both sidewalls of the channel hole 140T. The second semiconductor layer 133 may horizontally penetrate through the gate insulation layer 142 and contact the channel layer 144. Therefore, the gate insulation layer 142 may not exist at the same vertical level as the second semiconductor layer 133.

The buried insulation layer 146 may fill the internal space of the channel layer 144. The buried insulation layer 146 may include, for example, silicon oxide, silicon nitride, silicon oxynitride, or a combination thereof. According to embodiments, the buried insulation layer 146 may be omitted. In this case, the channel layer 144 may have a pillar shape without an internal space.

The conductive plug 148 may be in contact with the channel layer 144 at the upper portion of the channel hole 140T and block the entrance of the channel hole 140T. The conductive plug 148 may include, for example, a doped polysilicon film.

In the connection region CON, the plurality of gate lines 130 may extend to have a shorter length in the first horizontal direction (X direction) as the distance from the top surface of the common source line 110 increases. In other words, the plurality of gate lines 130 may have a cascade-like shape. In the connection region CON, the plurality of gate lines 130 having a cascade-like shape may be covered by the cover insulation layer 150. The cover insulation layer 150 may include, for example, an oxide, a nitride, or a combination thereof.

A first upper insulation layer 160 may be provided on the uppermost insulation layer 120H and the cover insulation layer 150, and a second upper insulation layer 180 may be provided on the first upper insulation layer 160. The first upper insulation layer 160 and the second upper insulation layer 180 may each include an oxide, a nitride, or a combination thereof.

In the memory cell region MEC, a bit line contact BLC may penetrate through the first upper insulation layer 160 and be connected to the channel structure 140. The bit line contact BLC may overlap the channel structure 140 in the vertical direction (Z direction). In the connection region CON, a contact structure 170 may extend in the vertical direction (Z direction) through the cover insulation layer 150 and the first upper insulation layer 160. The contact structure 170 may contact edge portions of each of the plurality of gate lines 130 having a cascade-like shape. The contact structure 170 may be configured to be connected to one gate line 130 selected from among the plurality of gate lines 130.

In the memory cell region MEC, the bit line BL is provided on the first upper insulation layer 160 and may be connected to the bit line contact BLC. In the connection region CON, an upper wiring line ML is provided on the first upper insulation layer 160 and may be connected to the contact structure 170. The bit line BL and the upper wiring line ML may be surrounded by the second upper insulation layer 180.

The integrated circuit memory device 100 according to embodiments may include the channel layer 144 including monocrystalline silicon crystallized through MILC and the second semiconductor layer 113 in contact with the channel layer 144, wherein the second semiconductor layer 113 may include the second semiconductor material layer 113b and the cover layer 113a provided between the channel layer 144 and the second semiconductor material layer 113b. Since the cover layer 113a including silicon carbonitride, silicon carbide, silicon nitride, silicon oxide, or a combination thereof is provided between the channel layer 144 and the second semiconductor material layer 113b, the metal silicide 145 included in the channel layer 144 may be prevented from diffusing into the second semiconductor material layer 113b during the process of manufacturing the integrated circuit memory device 100. By preventing diffusion of the metal silicide 145, the content of metals included in the second semiconductor material layer 113b may be about 0.04 at % or less. Therefore, a leakage current caused by the metal silicide 145 may be prevented, and thus the operational reliability of the integrated circuit memory device 100 may be improved.

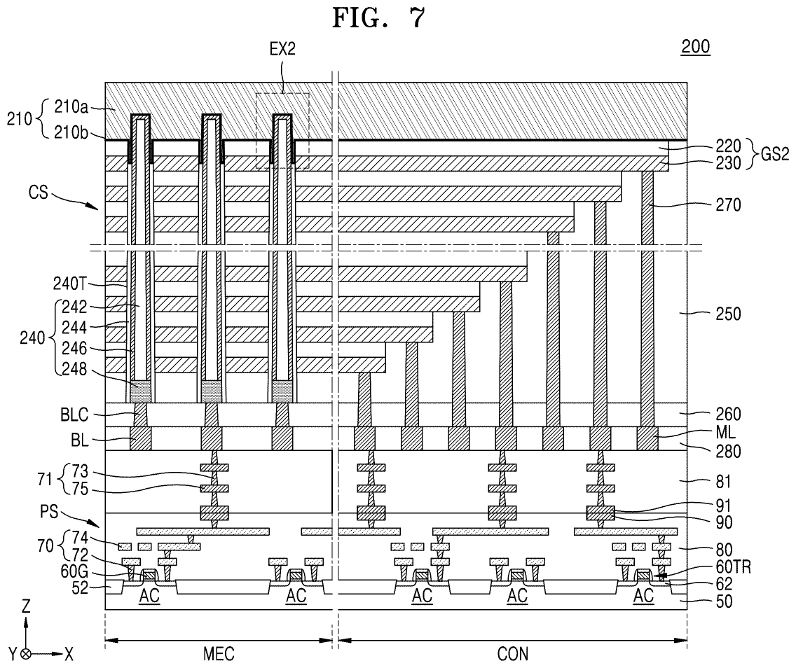

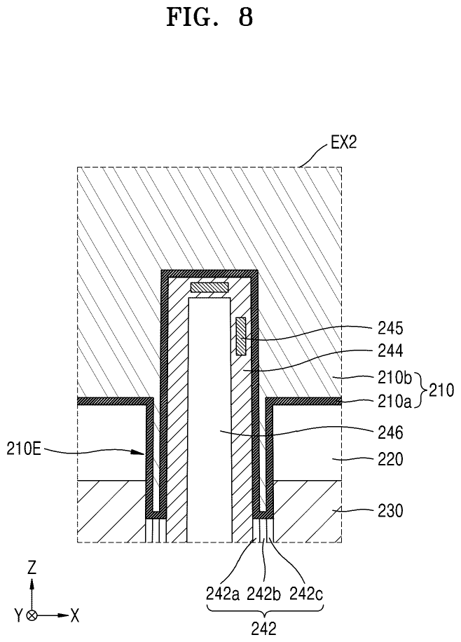

FIG. 7 is a cross-sectional view of some regions of the peripheral circuit structure PS and the cell array structure CS of an integrated circuit memory device 200 according to embodiments. FIG. 8 is an enlarged cross-sectional view of a portion EX2 of FIG. 7. Referring to FIGS. 7 and 8, the integrated circuit memory device 200 may include the peripheral circuit structure PS and the cell array structure CS, which extends on the peripheral circuit structure PS and overlaps the peripheral circuit structure PS in the vertical direction (Z direction).

According to embodiments, the integrated circuit memory device 200 may have a chip-to-chip (C2C) structure. The C2C structure may be obtained by forming the cell array structure CS on a first wafer, forming the peripheral circuit structure PS on a second wafer that is different from the first wafer, and then connecting the cell array structure CS and the peripheral circuit structure PS to each other by using a bonding method.

For example, the above-stated bonding method may refer to a method of bonding a first bonding pad 90 of the peripheral circuit structure PS and a second bonding pad 91 of the cell array structure CS, such that the first bonding pad 90 and the second bonding pad 91 may be electrically or physically connected to each other. According to embodiments, when a plurality of first bonding pads 90 and a plurality of second bonding pads 91 include copper (Cu), the bonding method may be a Cu—Cu bonding method. According to other embodiments, the plurality of first bonding pads 90 and the plurality of second bonding pads 91 may each include aluminum (Al) or tungsten (W).

The peripheral circuit structure PS of the integrated circuit memory device 200 may have a configuration generally similar to that of the peripheral circuit structure PS of the integrated circuit memory device 100 described above with reference to FIGS. 4, 5, and 6, except that the peripheral circuit structure PS of the integrated circuit memory device 200 includes the first bonding pad 90 formed at the top of the peripheral circuit structure PS.

The first bonding pad 90 may extend within the interlayer insulation layer 80. The first bonding pad 90 may be connected to the peripheral circuit wiring structure 70. According to embodiments, the top surface of the first bonding pad 90 may be at the same vertical level as the top surface of the interlayer insulation layer 80. The first bonding pad 90 may include a conductive material including, for example, copper (Cu), gold (Au), silver (Ag), aluminum (Al), tungsten (W), titanium (Ti), tantalum (Ta), or a combination thereof.

The cell array structure CS may include a gate stack GS2 extending on the peripheral circuit structure PS, a plurality of channel structures 240, and a common source line 210 extending on the gate stack GS2. The gate stack GS2 may include a plurality of insulation layers 220 and a plurality of gate lines 230 alternately stacked in the vertical direction (Z direction). The plurality of insulation layers 220 and the plurality of gate lines 230 may be substantially identical or similar to the plurality of insulation layers 120 and the plurality of gate lines 130 of the gate stack GS1 described above with reference to FIGS. 4, 5, and 6, respectively.

The plurality of channel structures 240 may extend in the vertical direction (Z direction) through the gate stack GS2. The plurality of channel structures 240 may each include a gate insulation layer 242, a channel layer 244, a buried insulation layer 246, and a conductive plug 248 arranged in a channel hole 240T. The gate insulation layer 242 may include a tunneling dielectric layer 242a, a charge storage layer 242b, and a blocking dielectric layer 242c sequentially arranged on sidewalls of the channel hole 240T. The channel layer 244 may include monocrystalline silicon crystallized through MILC. The channel layer 244 may include a metal silicide 245. Crystallization of monocrystalline silicon constituting the channel layer 244 may be performed through MILC using the metal silicide 245 as a seed.

The gate insulation layer 242, the channel layer 244, the buried insulation layer 246, and the conductive plug 248 that constitute each of the plurality of channel structures 240 may be substantially identical or similar to the gate insulation layer 142, the channel layer 144, the buried insulation layer 146, and the conductive plug 148 constituting the plurality of channel structures 140 described above with reference to FIGS. 4, 5 and 6, respectively.

The common source line 210 may be provided on the gate stack GS2. The common source line 210 may include a protrusion 210E that protrudes into the channel hole 240T and penetrates through the uppermost portion of the gate insulation layer 242 of each of the plurality of channel structures 240 in the vertical direction (Z direction). The common source line 210 may be in contact with the channel layer 244 of the channel structure 240 at the top surface of the channel structure 240 and the uppermost portions of both sidewalls of the channel structures 240. The common source line 210 may be directly connected to the channel layer 244 of a channel structure 240. The common source line 210 may include a semiconductor layer 210b and a cover layer 210a provided between the semiconductor layer 210b and the channel layer 144. The channel layer 144 and the semiconductor layer 210b may be spaced apart from each other with the cover layer 210a therebetween.

According to embodiments, the semiconductor layer 210b may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. According to embodiments, the semiconductor layer 210b may include a semiconductor doped with an impurity. According to embodiments, the semiconductor layer 210b may have a crystal structure including at least one selected from among monocrystalline, amorphous, and polycrystalline. The cover layer 210a may include carbide, nitride, oxide, or a combination thereof. The carbide may include, for example, silicon carbide. The nitride may include, for example, silicon nitride. The oxide may include, for example, silicon oxide.

According to embodiments, the semiconductor layer 210b may not include the metal silicide 245 included in the channel layer 244 of the channel structure 240. This may be because the cover layer 210a typically prevents the metal silicide 245 from diffusing from the channel layer 244 to the semiconductor layer 210b.

In the connection region CON, the plurality of gate lines 230 may extend to have a shorter length in the first horizontal direction (X direction) as the distance from the common source line 210 increases. In other words, the plurality of gate lines 230 may have an inverted cascade-like shape. In the connection region CON, the plurality of gate lines 230 having an inverted cascade-like shape may be covered by a cover insulation layer 250. A first lower insulation layer 260 may be disposed on the bottom surface of the lowermost insulation layer 220 and the bottom surface of the cover insulation layer 250, and a second lower insulation layer 280 may be disposed on the bottom surface of the first lower insulation layer 260. The cover insulation layer 250, the first lower insulation layer 260, and the second lower insulation layer 280 of the integrated circuit memory device 200 may be substantially identical or similar to the cover insulation layer 150, the first upper insulation layer 160, and the second upper insulation layer 180 described above with reference to FIGS. 4, 5, and 6, respectively.

In the memory cell region MEC, a bit line contact BLC may penetrate through the first lower insulation layer 260 and be electrically connected to the channel structure 240. The bit line contact BLC may overlap the channel structure 240 in the vertical direction (Z direction). In the connection region CON, a contact structure 270 may extend in the vertical direction (Z direction) through the cover insulation layer 250 and the first lower insulation layer 260.

In the memory cell region MEC, the bit line BL is disposed on the bottom surface of the first lower insulation layer 260 and may be connected to the bit line contact BLC. In the connection region CON, a lower wiring line ML is disposed on the second lower insulation layer 280 and may be connected to the contact structure 270. The bit line BL and the lower wiring line ML may be surrounded by the second lower insulation layer 280.

At least portions of the bit line BL and the contact structure 270 may be in contact with a connection wiring structure 71 on the bottom surfaces thereof. The connection wiring structure 71 may include a plurality of connection wiring contacts 73 and a plurality of connection wiring layers 75. The plurality of connection wiring layers 75 may have a multi-layered structure including a plurality of metal layers arranged at different vertical levels. The connection wiring structure 71 may include tungsten, titanium, tantalum, copper, aluminum, titanium nitride, tantalum nitride, tungsten nitride, or a combination thereof. The bottom surface of the connection wiring structure 71 may be in contact with the second bonding pad 91. The connection wiring structure 71 may be connected to the second bonding pad 91. The bottom surface of the second bonding pad 91 may be in contact with the top surface of the first bonding pad 90. The first bonding pad 90 and the second bonding pad 91 may be connected to each other. The peripheral circuit structure PS and the cell array structure CS may be connected to each other through the first bonding pad 90 and the second bonding pad 91. The second bonding pad 91 may include a material that is substantially identical or similar to the material constituting the first bonding pad 90. The connection wiring structure 71 and the second bonding pad 91 may be covered by a connection insulation layer 81. The connection insulation layer 81 may include, for example, a silicon oxide film, a silicon nitride film, a SiON film, a SiOCN film, or a combination thereof.

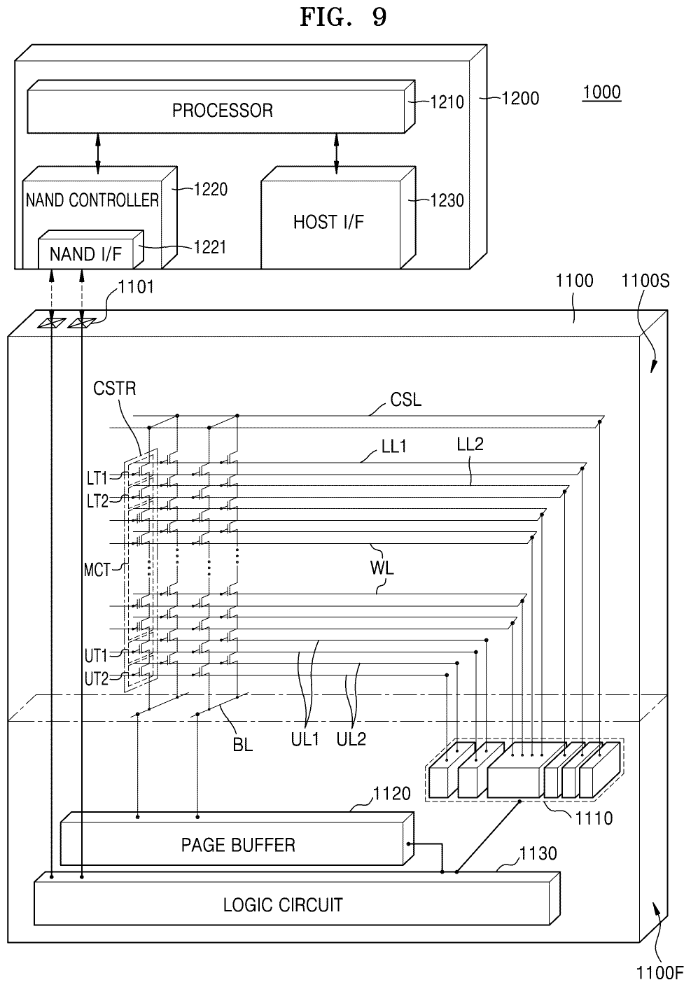

FIG. 9 is a diagram schematically showing an electronic system 1000 including an integrated circuit memory device, according to an embodiment. Referring to FIG. 9, the electronic system 1000 according to an embodiment may include an integrated circuit memory device 1100 and a controller 1200 electrically connected to the integrated circuit memory device 1100. The electronic system 1000 may be a storage device including one or a plurality of integrated circuit memory devices 1100 or an electronic device including the storage device. For example, the electronic system 1000 may be a solid state drive (SSD) device, a universal serial bus (USB) device, a computing system, a medical device, or a communication device including at least one integrated circuit memory device 1100.

The integrated circuit memory device 1100 may be a non-volatile memory device. For example, the integrated circuit memory device 1100 may be a NAND flash memory device including at least one of the structures described above with respect to integrated circuit memory devices 100 to 200 with reference to FIGS. 4, 5, 6, 7, and 8. The integrated circuit memory device 1100 may include a first structure 1100F and a second structure 1100S on the first structure 1100F. According to embodiments, the first structure 1100F may also be disposed next to the second structure 1100S. The first structure 1100F may be a peripheral circuit structure including a decoder circuit 1110, a page buffer 1120, and a logic circuit 1130. The second structure 1100S may be a memory cell structure including the bit lines BL, the common source line CSL, the plurality of word lines WL, first and second gate upper lines UL1 and UL2, first and second gate lower lines LL1 and LL2, and a plurality of memory cell strings CSTR between the bit lines BL and the common source line CSL.

In the second structure 1100S, the plurality of memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may be variously changed according to embodiments.

According to embodiments, the upper transistors UT1 and UT2 may include string select transistors, and the lower transistors LT1 and LT2 may include ground select transistors. The first and second gate lower lines LL1 and LL2 may be gate electrodes of the lower transistors LT1 and LT2, respectively. The word line WL may be a gate electrode of a memory cell transistor MCT, and the first and second gate upper lines L1 and UL2 may be gate electrodes of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110 through a plurality of first connection wires 1115 extending from the inside of the first structure 1100F to the second structure 1100S. The plurality of bit lines BL may be electrically connected to the page buffer 1120 through a plurality of second connection wires 1125 extending from the inside of the first structure 1100F to the second structure 1100S.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130. The integrated circuit memory device 1100 may communicate with the controller 1200 through an input/output pad 1101 electrically connected to the logic circuit 1130. The input/output pad 1101 may be electrically connected to the logic circuit 1130 through an input/output connection wire extending from the inside of the first structure 1100F to the second structure 1100S. The controller 1200 may include a processor 1210, a NAND controller 1220, and a host interface 1230. According to some embodiments, the electronic system 1000 may include a plurality of integrated circuit memory devices 1100, and, in this case, the controller 1200 may control the plurality of integrated circuit memory devices 1100.

The processor 1210 may control the overall operation of the electronic system 1000 including the controller 1200. The processor 1210 may operate according to certain firmware and may access the integrated circuit memory device 1100 by controlling the NAND controller 1220. The NAND controller 1220 may include a NAND interface 1221 that handles communication with the integrated circuit memory device 1100. Control commands for controlling the integrated circuit memory device 1100, data to be written to the memory cell transistors MCT of the integrated circuit memory device 1100, and data to be read from the memory cell transistors MCT of the integrated circuit memory device 1100 may be transmitted through the NAND interface 1221. The host interface 1230 may provide the function for communication between the electronic system 1000 and an external host. When a control command is received from an external host through the host interface 1230, the processor 1210 may control the integrated circuit memory device 1100 in response to the control command.

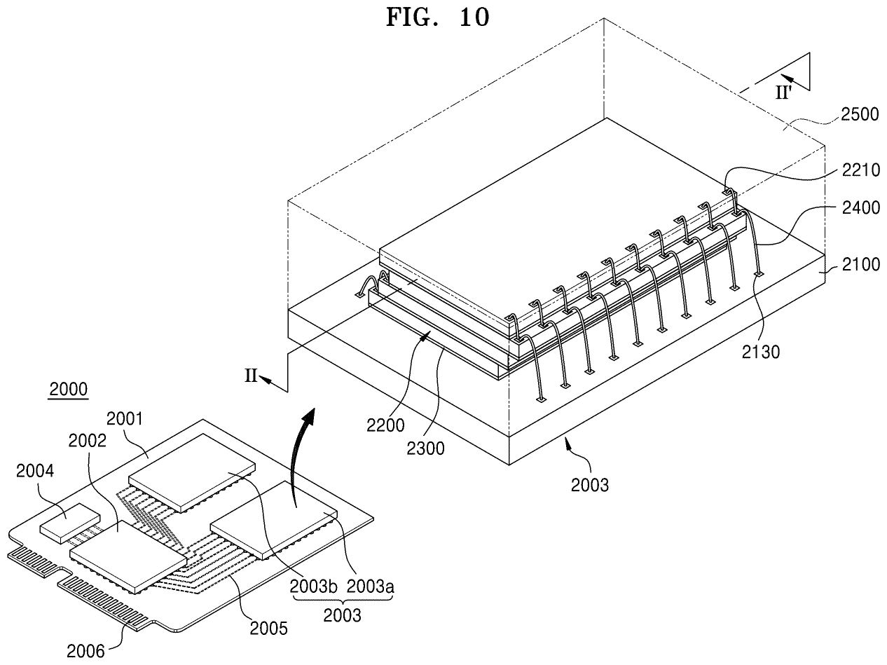

FIG. 10 is a schematic perspective view of an electronic system 2000 including an integrated circuit memory device, according to an embodiment. Referring to FIG. 10, the electronic system 2000 according to an example embodiment of the inventive concept may include a main substrate 2001 and a controller 2002, one or more semiconductor packages 2003, and DRAM 2004 that are mounted on the main substrate 2001. The semiconductor package 2003 and the DRAM 2004 may be connected to the controller 2002 by a plurality of wiring patterns 2005 formed on the main substrate 2001.

The main substrate 2001 may include a connector 2006 including a plurality of pins coupled to an external host. The number and arrangement of the pins of the connector 2006 may vary according to a communication interface between the electronic system 2000 and the external host. According to embodiments, the electronic system 2000 may communicate with an external host according to any one of interfaces including USB, peripheral component interconnect express (PCI-Express), serial advanced technology attachment (SATA), M-Phy for universal flash storage (UFS), etc. According to embodiments, the electronic system 2000 may operate by power supplied from an external host through the connector 2006. The electronic system 2000 may further include a power management integrated circuit (PMIC) that distributes power supplied from the external host to the controller 2002 and the semiconductor package 2003. The controller 2002 may write data to or read data from the semiconductor package 2003 and may improve the operating speed of the electronic system 2000.

The DRAM 2004 may be a buffer memory for mitigating the speed difference between the semiconductor package 2003, which is a data storage space, and an external host. The DRAM 2004 included in the electronic system 2000 may also operate as a type of cache memory and may provide a space for temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, the semiconductor chips 2200 on the package substrate 2100, an adhesive layer 2300 disposed on the bottom surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including a plurality of package upper pads 2130. The semiconductor chips 2200 may each include input/output pads 2210. The input/output pad 2210 may correspond to the input/output pad 1101 of FIG. 9. The plurality of semiconductor chips 2200 may each include a plurality of gate stacks 3210 and a plurality of channel structures 3220. The plurality of semiconductor chips 2200 may each include at least one of the structures described above with respect to the integrated circuit memory devices 100 to 200 with reference to FIGS. 3, 4, 5, 6, 7, and 8.

According to embodiments, the connection structure 2400 may be a bonding wire electrically connecting the input/output pad 2210 and the package upper pad 2130. Therefore, in the first and second semiconductor packages 2003a and 2003b, the semiconductor chips 2200 may be electrically connected to one another through bonding wires and may be electrically connected to the package upper pads 2130 of the package substrate 2100. According to embodiments, in the first and second semiconductor packages 2003a and 2003b, the semiconductor chips 2200 may be connected to one another through a connection structure including through silicon vias (TSVs) instead of the connection structure 2400 including bonding wires.

According to embodiments, the controller 2002 and the semiconductor chips 2200 may be included in one package. According to embodiment, the controller 2002 and the semiconductor chips 2200 may be mounted on a separate interposer substrate that is different from the main substrate 2001 and the controller 2002 and the semiconductor chips 2200 may be connected to each other through wires formed on the interposer substrate.

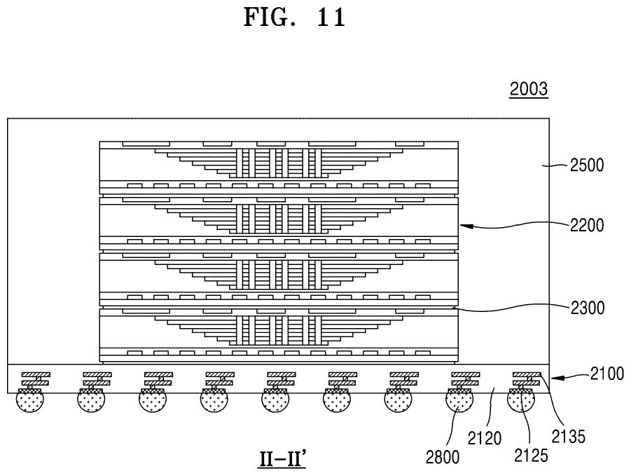

FIG. 11 is a schematic cross-sectional view of semiconductor packages 2003 according to embodiments. FIG. 11 shows a configuration along a line II-II′ of FIG. 10 in more detail. Referring to FIG. 11, in a semiconductor package 2003, the package substrate 2100 may be a printed circuit board. The package substrate 2100 may include a package substrate body 2120, a plurality of package upper pads 2130 (refer to FIG. 10) arranged on the top surface of the package substrate body 2120, a plurality of package lower pads 2125 arranged or exposed on the bottom surface of the package substrate body 2120, and a plurality of internal wires 2135 electrically connecting the package upper pads 2130 and the package lower pads 2125 inside the package substrate body 2120. The plurality of upper pads 2130 may be electrically connected to a plurality of connection structures 2400. The plurality of lower pads 2125 may be connected to the plurality of wiring patterns 2005 on the main substrate 2001 of the memory system 2000 shown in FIG. 10 through a plurality of conductive connections 2800.

According to embodiments,, the plurality of semiconductor chips 2200 may each include at least one of the structures described above with respect to the integrated circuit memory devices 100 to 200 with reference to FIGS. 3, 4, 5, 6, 7, and 8.

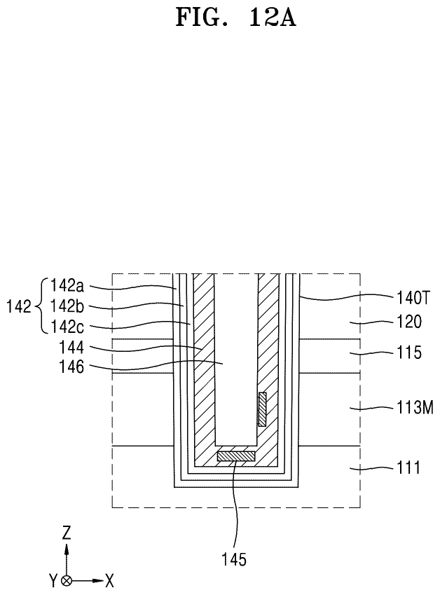

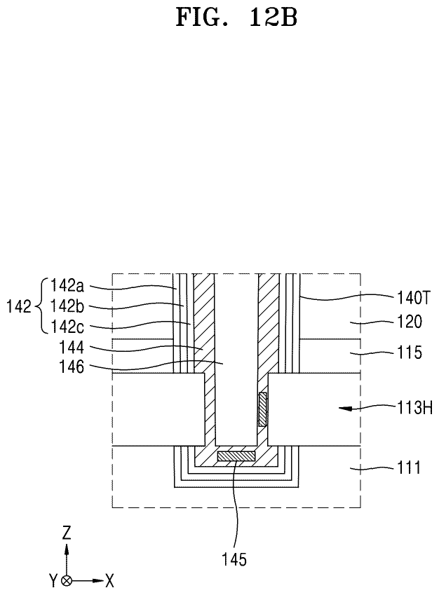

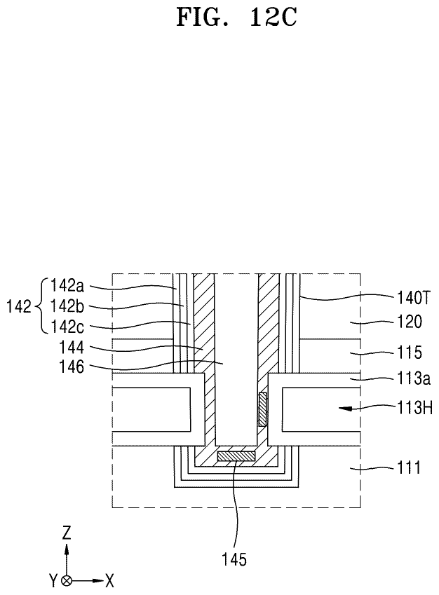

FIGS. 12A, 12B, and 12C are cross-sectional views to describe a method of manufacturing the integrated circuit memory device 100, according to embodiments. FIGS. 12A, 12B, and 12C are cross-sectional views showing a region corresponding to EX1 of FIG. 5 according to the manufacturing process sequence of the integrated circuit memory device 100.

Referring to FIG. 12A, the first semiconductor layer 111, a sacrificial layer 113M, and the third semiconductor layer 115 may be sequentially formed on the peripheral circuit structure PS (refer to FIG. 4) provided on the substrate 50. Next, the plurality of insulation layers 120 (refer to FIG. 4) and a plurality of stack sacrificial layers (not shown) may be formed one-by-one alternately on the third semiconductor layer 115. The plurality of insulation layers 120 may include silicon oxide, and the plurality of stack sacrificial layers may include silicon nitride, for example.

Next, the plurality of channel structures 140 extending through the plurality of insulation layers 120 and the plurality of stack sacrificial layers in the vertical direction (Z direction) may be formed. The plurality of channel structures 140 may each penetrate through the sacrificial layer 113M and the third semiconductor layer 115 and extend into the first semiconductor layer 111.

First, the gate insulation layer 142 including the tunneling dielectric layer 142a, the charge storage layer 142b, and the blocking dielectric layer 142c may be formed on the inner wall of the channel hole 140T, and the channel layer 144 may be formed on the gate insulation layer 142. At this time, the channel layer 144 may include amorphous silicon. According to embodiments, the channel layer 144 may include amorphous silicon doped with an impurity. The impurity may include, for example, O, C, N, or a combination thereof. When the channel layer 144 includes amorphous silicon doped with an impurity, the impurity may prevent the amorphous silicon from being crystallized by the heat instead of MILC due to an annealing process performed during crystallization of the channel layer 144, which will be described later.

Next, the crystallization of the channel layer 144 may be performed. The crystallization may be performed by first forming the metal silicide 145 on the top surface of the channel layer 144 and then performing an annealing process on the metal silicide 145. The metal silicide 145 may include, for example, nickel silicide, cobalt silicide, platinum silicide, or a combination thereof. For example, the annealing process may be performed at a temperature from about 500° C. to about 800° C. According to embodiments, the annealing process may be batch annealing or rapid thermal annealing (RTA). Through the annealing process, the metal silicide 145 may move downward along the channel layer 144 while crystallizing the channel layer 144 through MILC. The amorphous silicon constituting the channel layer 144 may be crystallized into monocrystalline silicon through the annealing process. Next, the buried insulation layer 146 filling the internal space of the channel layer 144 may be formed, and the conductive plug 148 may be formed on the channel layer 144.

Referring to FIG. 12B, in a result structure of FIG. 12A, the sacrificial layer 113M may be removed to form a hole 113H. The hole 113H may further extend horizontally from the sacrificial layer 113M and horizontally penetrate through the gate insulation layer 142 of each of the plurality of channel structures 140. The outer walls of the channel layer 144 of the channel structure 140 located at the same vertical level as the hole 113H may be exposed by the hole 113H.

Referring to FIG. 12C, in a result structure of FIG. 12B, the cover layer 113a covering the inner wall of the hole 113H may be formed. The cover layer 113a may include, for example, silicon carbide, silicon nitride, silicon oxide, or a combination thereof. The cover layer 113a may be formed, for example, through a deposition process. Next, in a result structure of FIG. 12C, the second semiconductor layer 113 may be formed by forming the second semiconductor material layer 113b that fills the inner space of the cover layer 113a. The second semiconductor material layer 113b may be formed, for example, through a deposition process. Next, after forming the word line cuts WLC (refer to FIG. 4) penetrating through the plurality of insulation layers 120 and the plurality of stack sacrificial layers, the plurality of stack sacrificial layers exposed through the word line cuts WLC may be selectively removed, and the plurality of gate lines 130 (refer to FIG. 5) may be formed by filling spaces formed by removing the plurality of stack sacrificial layers with a conductive material. The interior of the word line cuts WLC may be filled with the word line cut structure 192 (refer to FIG. 4). Then, by forming the bit line contact BLC (refer to FIG. 5) connected to the plurality of channel structures 140 and the bit line BL (refer to FIG. 5) connected to the bit line contact BLC, the integrated circuit memory device 100 illustrated in FIGS. 4, 5 and 6 may be manufactured.

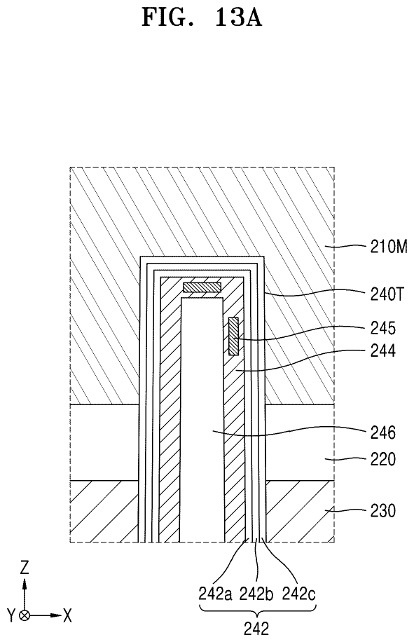

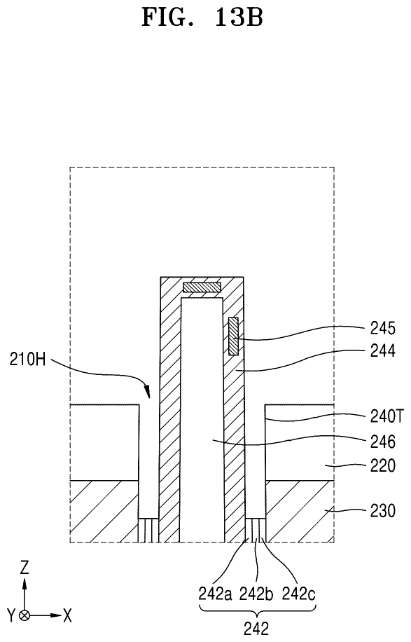

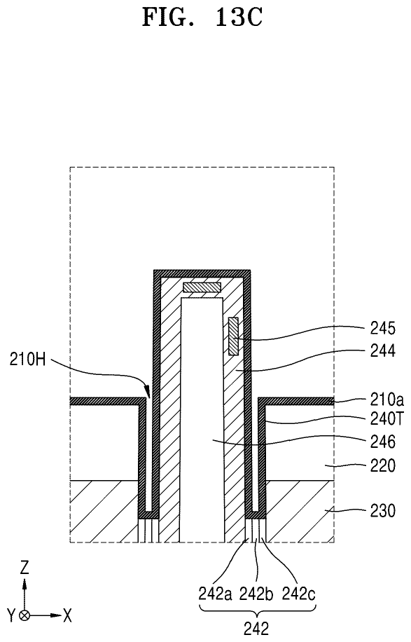

FIGS. 13A, 13B, and 13C are cross-sectional views to describe a method of manufacturing the integrated circuit memory device 200, according to embodiments. FIGS. 13A, 13B, and 13C are cross-sectional views showing a region corresponding to EX2 of FIG. 7 according to the manufacturing process sequence of the integrated circuit memory device 200. Referring to FIG. 13A, the plurality of insulation layers 220 (refer to FIG. 7) and a plurality of stack sacrificial layers (not shown) may be formed one by one alternately on a provided sub-substrate 210M. The plurality of insulation layers 220 may include silicon oxide, and the plurality of stack sacrificial layers may include silicon nitride, for example.

Next, the plurality of channel structures 240 extending through the plurality of insulation layers 220 and the plurality of stack sacrificial layers in the vertical direction (Z direction) may be formed.

In detail, the gate insulation layer 242 including the tunneling dielectric layer 242a, the charge storage layer 242b, and the blocking dielectric layer 242c may be formed on the inner wall of the channel hole 240T, and the channel layer 244 may be formed on the gate insulation layer 242. At this time, the channel layer 244 may include amorphous silicon. Next, crystallization of the channel layer 244 may be performed. The crystallization may be performed through MILC using the metal silicide 245 included in the channel layer 244, as described above with reference to FIG. 12A. The amorphous silicon constituting the channel layer 244 may be crystallized into monocrystalline silicon through MILC.

Next, the buried insulation layer 246 filling the internal space of the channel layer 244 may be formed, and the conductive plug 248 may be formed on the channel layer 244. Then, after forming the word line cuts (not shown) penetrating through the plurality of insulation layers 220 and the plurality of stack sacrificial layers, the plurality of stack sacrificial layers exposed through the word line cuts may be selectively removed, and the plurality of gate lines 230 (refer to FIG. 7) may be formed by filling spaces formed by removing the plurality of stack sacrificial layers with a conductive material.

Following this, the bit line contact BLC (refer to FIG. 7) connected to the plurality of channel structures 140 and the bit line BL connected to the bit line contact BLC are formed on the plurality of channel structures 240, the connection wiring structure 71 (refer to FIG. 7) and the second bonding pad 91 (refer to FIG. 7) may be formed on the bit line BL. Then, the peripheral circuit structure PS (refer to FIG. 7) on which the first bonding pad 90 (refer to FIG. 7) is formed may be provided, and the first bonding pad 90 of the peripheral circuit structure PS and the second bonding pad 91 may be bonded to each other. According to embodiments, the first bonding pad 90 and the second bonding pad 91 may be bonded through thermocompression.

Referring to FIG. 13B, the sub-substrate 210M may be removed from a result structure of FIG. 13A. Next, the uppermost portion of the gate insulation layer 242 may be partially removed through a butting process. As the uppermost portion of the gate insulation layer 242 is partially removed, a protruding hole 210H extending into the channel hole 240T may be formed. As the sub-substrate 210M is removed, the top surface of the uppermost insulation layer 220 may be exposed, and some of surfaces of the channel layer 244 may be exposed by the protruding hole 210H.

Referring to FIG. 13C, in a result structure of FIG. 13B, the cover layer 210athat covers the exposed top surface of the uppermost insulation layer 220 and an exposed surface of the channel layer 244 may be formed. The cover layer 210a may be formed, for example, through a deposition process. Next, the integrated circuit memory device 200 illustrated in FIGS. 7 and 8 may be formed by forming the semiconductor layer 210b (refer to FIG. 7) on the cover layer 210a in a result structure of FIG. 13B.

While the inventive concept has been particularly shown and described with reference to embodiments thereof, it will be understood that various changes in form and details may be made therein without departing from the spirit and scope of the following claims.

What is claimed is:

1. An integrated circuit device, comprising:
a substrate having a peripheral circuit structure thereon; and
a memory cell array structure extending on the peripheral circuit structure, said memory cell array structure comprising:
a common source line configured as a first semiconductor layer, a second semiconductor layer, and a third semiconductor layer sequentially stacked on the substrate;
a gate stack on the common source line, said gate stack including a plurality of insulation layers and a plurality of gate lines that are alternately arranged; and
a plurality of channel structures that each respectively comprise a monocrystalline channel layer, which penetrates through the gate stack in a vertical direction perpendicular to a top surface of the substrate; and
wherein the second semiconductor layer extends from side walls of a channel structure and is in electrical contact with a corresponding monocrystalline channel layer within the channel structure; and
wherein the second semiconductor layer is configured to include a second semiconductor material layer and a cover layer provided between the monocrystalline channel layer and the second semiconductor material layer.

2. The device of claim 1, wherein the cover layer comprises a material selected from a group consisting of silicon carbide, silicon nitride, silicon oxide, and combinations thereof.

3. The device of claim 1, wherein the monocrystalline channel layer comprises a metal silicide.

4. The device of claim 3, wherein the metal silicide is selected from a group consisting of nickel silicide, cobalt silicide, platinum silicide, and combinations thereof.

5. The device of claim 1, wherein the second semiconductor material layer does not comprise a metal silicide.

6. The device of claim 1, wherein the second semiconductor material layer comprises polysilicon doped with an impurity selected from a group consisting of phosphorus (P), boron (B), arsenic (As), and combinations thereof.

7. The device of claim 1, wherein the plurality of channel structures penetrate through the second semiconductor layer and the third semiconductor layer and extend into the first semiconductor layer.

8. The device of claim 1, wherein the plurality of channel structures comprise a gate insulation layer covering both sidewalls and a bottom surface of a channel hole penetrating through the gate stack, and the channel layer is disposed on the gate insulation layer.

9. An integrated circuit device, comprising:
a substrate having a peripheral circuit structure thereon; and
a cell array structure extending on the peripheral circuit structure, said cell array structure comprising:
a gate stack comprising a plurality of insulation layers and a plurality of gate lines alternately arranged on the substrate;
a plurality of channel structures each penetrating through the gate stack in a vertical direction perpendicular to a top surface of the substrate and comprising a monocrystalline channel layer; and
a common source line that extends on the gate stack, is in contact with the channel layer of the channel structure, and comprises a semiconductor layer and a cover layer provided between the semiconductor layer and the channel layer.

10. The device of claim 9, wherein the cover layer comprises silicon carbide, silicon nitride, silicon oxide, or a combination thereof.

11. The device of claim 9, wherein the channel layer comprises a metal silicide, but the semiconductor layer does not comprise a metal silicide.

12. The device of claim 9, wherein the common source line comprises a protrusion penetrating through a portion of the channel structure.

13. The device of claim 12, wherein the protrusion of the common source line is in contact with the channel layer of the channel structure.

14. The device of claim 9, wherein the semiconductor layer comprises polysilicon doped with an impurity comprising phosphorus (P), boron (B), arsenic (As), or a combination thereof.

15. The device of claim 9, wherein the peripheral circuit structure further comprises a plurality of first bonding pads, and the cell array structure further comprises a plurality of second bonding pads, and wherein the plurality of first bonding pads and the plurality of second bonding pads are bonded to each other.

16. An electronic system, comprising:
a main substrate;
an integrated circuit device on the main substrate; and
a controller electrically connected to the integrated circuit device on the main substrate;
wherein the integrated circuit device comprises:
a peripheral circuit structure provided on a substrate; and
a cell array structure extending on the peripheral circuit structure, said cell array structure comprising:
a common source line comprising a first semiconductor layer, a second semiconductor layer, and a third semiconductor layer sequentially disposed on the substrate;
a gate stack comprising a plurality of insulation layers and a plurality of gate lines alternately arranged on the common source line; and
a plurality of channel structures each penetrating through the gate stack in a vertical direction perpendicular to a top surface of the substrate and comprising a monocrystalline channel layer;
wherein the second semiconductor layer extends from both side walls of a channel structure into the channel structure and is in contact with the channel layer; and
wherein the second semiconductor layer comprises a second semiconductor material layer and a cover layer provided between the channel layer and the second semiconductor material layer.

17. The electronic system of claim 16, wherein the cover layer comprises silicon carbide, silicon nitride, silicon oxide, or a combination thereof.

18. The electronic system of claim 16, wherein the channel layer comprises a metal silicide, and the semiconductor layer does not comprise a metal silicide.

19. The electronic system of claim 16, wherein the plurality of channel structures penetrate through the second semiconductor layer and the third semiconductor layer and extend into the first semiconductor layer.

20. The electronic system of claim 16, wherein the plurality of channel structures comprise a gate insulation layer covering both sidewalls and a bottom surface of a channel hole penetrating through the gate stack, and the channel layer extends on the gate insulation layer.
